(19) United States
(12) Patent Application Publication
(10) Pub. No.: US 2023/0326840 A1
(43) Pub. Date: Oct. 12, 2023

(54) SYSTEM AND METHOD FOR INTEGRATED CIRCUIT (IC) NANOMETER RANGE INTERCONNECT FABRICATION

(71) Applicant: Meta Platforms, Inc., Menlo Park, CA (US)

(72) Inventors: Pradip Sairam PICHUMANI, Bellevue, WA (US); Sandeep REKHI, San Jose, CA (US); Ahmad BYAGOWI, Mountain View, CA (US)

(73) Assignee: Meta Platforms, Inc., Menlo Park, CA (US)

(21) Appl. No.: 17/702,293

(22) Filed: Mar. 23, 2022

(51) Int. Cl. H01L 21/48; H01L 23/498

(52) U.S. Cl. CPC H01L 23/49811; H01L 21/4853

(57) ABSTRACT

According to examples, an interconnect system for integrated circuits (ICs) may be fabricated by processing a substrate implanted with copper wells with a photoresist layer such that remaining portions of the photoresist layer expose portions of the copper wells; depositing a barrier layer over a top surface of the wafer, depositing a seed copper layer over the barrier layer; depositing a copper layer over the seed copper layer; planarizing the copper layer and portions of the barrier layer; depositing another copper layer over exposed portions of the substrate, the copper wells, and the interconnect cores; removing portions of the other copper layer between interconnects by processing the second copper layer with another photoresist layer; and removing remaining portions of the other photoresist layer on the interconnects.

### TECHNICAL FIELD

This patent application relates generally to integrated circuit (IC) interconnect fabrication, and more specifically, to generating copper-based, high-density, small-size interconnections between a die and a package through damascene lithography.

### BACKGROUND

A variety of interconnect systems are used in IC packaging to provide electrical connections between a die that includes circuitry and packaging for the IC. Due to size and material characteristics, the interconnect system may be a leading component in power consumption, heat generation, and signal delays in an IC. For example, long and convoluted connections, material impedance mismatches (when multiple conductive materials are used) may result in higher power consumption and heat generation. Excessive heat may degrade an IC’s performance.

With the increased demand for more functionality and higher density for ICs, interconnect systems such as wafer-to-wafer (W2W) are developed. However, such newer systems are vulnerable to alignment issues, higher cost, etc., while still utilizing some of the older technologies such as conventional solder ball or pillar connections.

### BRIEF DESCRIPTION OF DRAWINGS

Features of the present disclosure are illustrated by way of example and not limited in the following figures, in which like numerals indicate like elements. One skilled in the art will readily recognize from the following that alternative examples of the structures and methods illustrated in the figures can be employed without departing from the principles described herein.

FIG. 1A illustrates a cross-sectional view of an IC with wire-bond connections between the die and the packaging, according to an example.

FIGS. 1B-1D illustrate various conventional interconnect systems such as solder bond, pillar, wafer-to-wafer (W2W), according to examples.

FIG. 2 illustrates a cross-sectional view of an IC interconnects system with small-size, high-density, copper interconnects, according to an example.

FIGS. 3A-3C illustrate cross-sectional views of a small-size, high-density copper interconnect system in various stages of fabrication, according to an example.

FIG. 4 illustrates a functional block diagram of a system to fabricate a small-size, high-density, copper interconnect system, according to an example.

FIG. 5 illustrates a flowchart of a method to fabricate a small-size, high-density, copper interconnect system, according to an example.

### DETAILED DESCRIPTION

For simplicity and illustrative purposes, the present application is described by referring mainly to examples thereof. In the following description, numerous specific details are outlined in order to provide a thorough understanding of the present application. It will be readily apparent, however, that the present application may be practiced without limitation to these specific details. In other instances, some methods and structures readily understood by one ordinarily skilled in the art have not been described in detail so as not to unnecessarily obscure the present application. As used herein, the terms “a” and “an” are intended to denote at least one of a particular element, the term “includes” means includes but not limited to, the term “including” means including but not limited to, and the term “based on” means based at least in part on.

As discussed herein, while a variety of interconnect systems exist for integrated circuits (ICs), a majority of the commonly implemented systems such as wire-bond connections may not lend themselves to the growing need for higher density, faster circuitry. Interconnect systems with higher density configurations such as wafer-to-wafer (W2W) and ball-grid array (BGA) bonding systems may be more complex and costly to fabricate (smaller yields) while still having power consumption, heat generation, and signal speed challenges.

Disclosed herein are systems, apparatuses, and methods that may provide a small-size, high-density, copper interconnect system for integrated circuits (ICs). Example interconnect systems may be fabricated utilizing the Damascene lithography process to generate interconnections in nanometer range for an interface between a die and a package. Through the reduction of interconnection lines and layers (backend of line “BEOL” layers) and use of single material (copper), example interconnect systems may reduce power consumption, heat generation, and signal delays. As a result of these reductions, higher frequencies may be implemented on ICs.

In some examples, a separation distance between the interconnects may be in a range of tens of nanometers (for example, from about 200 nm nanometers to about 1000 nm nanometers in some practical implementations). The example range provided is for illustration purposes and is not intended as a limit to example implementations. The added complexity and cost of generating under bump metallurgy (UBM) on the die side may be avoided if copper interconnects can directly contact the die. A pitch (and thereby a density) of the interconnect system may be subject to limitations of the Damascene lithography process (not the interconnection method) allowing nanometer range interconnects. Due to the smaller size / higher density, an example interconnect system may have the fewer backend of line (BEOL) layers and may allow mounting of the die directly on a printed circuit board (PCB). The latter feature may eliminate a need for packaging potentially resulting in substantial cost and complexity reduction. Furthermore, the number of pins on the IC may be increased drastically due to the increased density of the interconnect system. Other benefits and advantages may also be apparent.

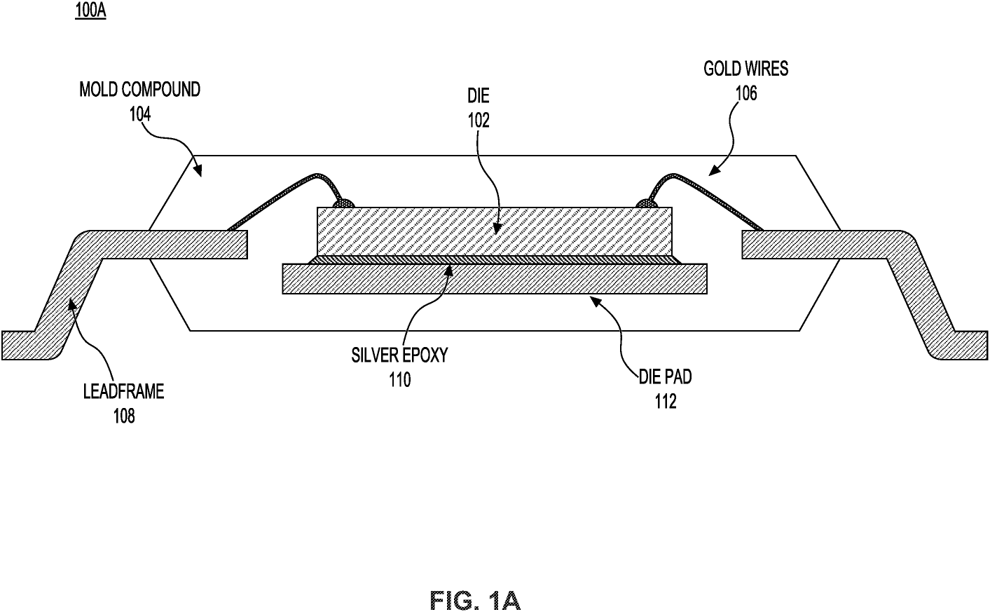

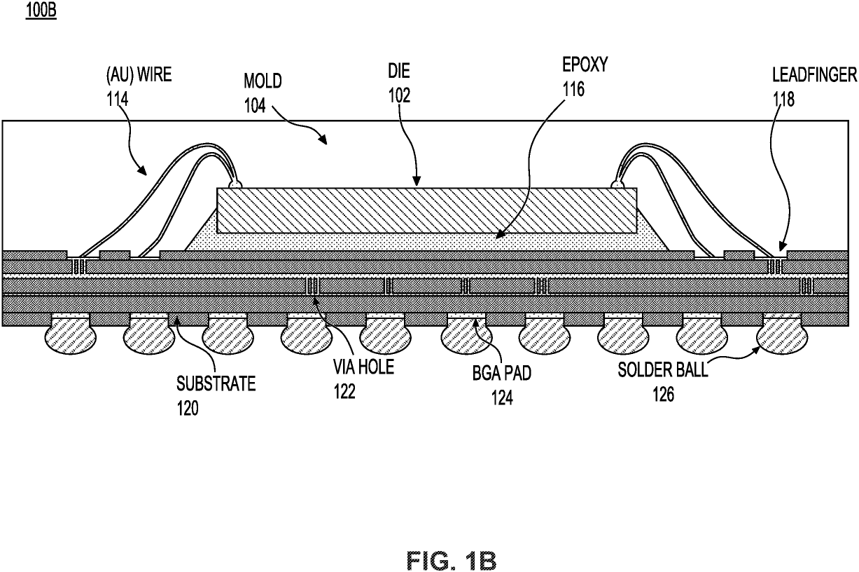

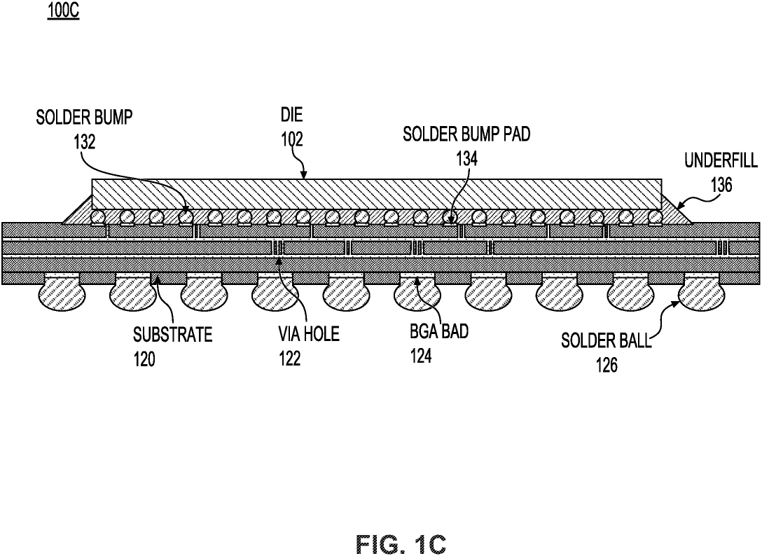

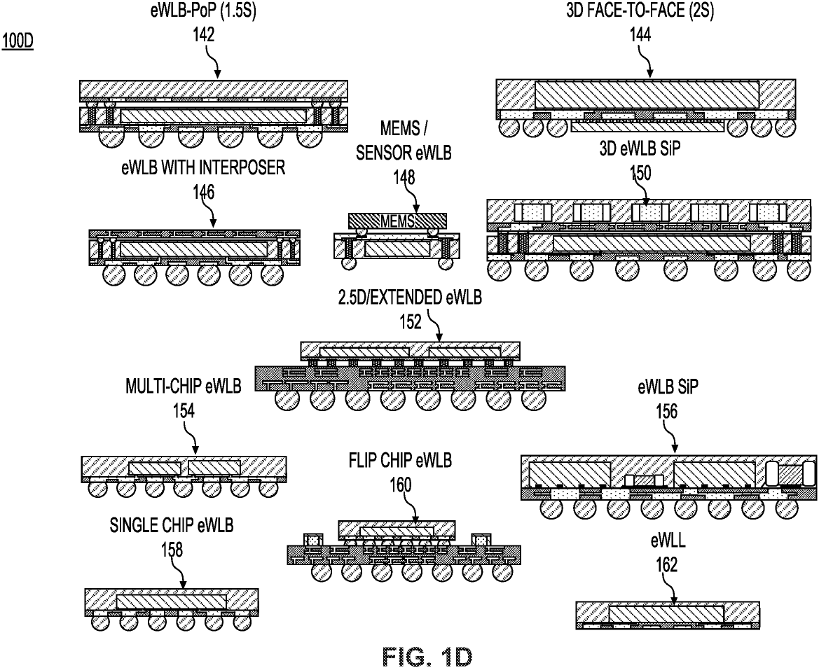

FIG. 1A illustrates a cross-sectional view of an IC with wire-bond connections between the die and the packaging, according to an example. Diagram 100A shows an integrated circuit where a die 102 is bonded through a silver epoxy 110 to a die pad 112. Circuits within the die 102 are electrically connected to the outside world (other devices) through the lead frame 108 of the packaging, which includes the lead frame 108 and mold compound 104. The connection between the die 102 and the lead frame 108 is provided through gold wires 106 (wire-bond).

Wire-bonding is a well-developed bonding technique. To improve performance and reliability higher quality metals such as gold may be used in the wire-bond. However, wire-bonding suffers from two major challenges. First challenge is density. Because of the type of connection (wires), wire-bonding may not lend itself to higher density circuits with a relatively large number of interconnections. Secondly, regardless of the metal used, length, and type of wire-bond connection, this system may cause substantial power consumption, heat generation, and consequently signal delay in the interconnections. Specifically, higher frequency ICs may have limitations imposed on their clock frequencies because of the wire-bond interconnect system.

Increased power consumption, heat build-up, and signal delays due to the interconnect system may degrade the performance of an integrated circuit (IC) substantially. Additionally, heat build-up may cause failures, warpage, and other thermal management issues.

FIGS. 1B through 1D illustrate various conventional interconnect systems such as solder bond, pillar, wafer-to-wafer (W2W), according to examples. Diagram 100B in FIG. 1B shows an integrated circuit (IC) configuration, where the interconnect system for die 102 includes wire-bonds 114 (gold wire) coupling contact pads (not shown) on the top surface of the die 102 to lead fingers 118 on a top layer of a backend of line (BEOL) that includes interconnection lines in layers and via holes 122 in a substrate 120 and an array of ball-grid array (BGA) pads 124 for connection to solder balls 126. The die 102 is held in place using epoxy 116 and mold 104. Diagram 100C in FIG. 1C shows another integrated circuit (IC) configuration, where the interconnect system for die 102 includes solder bumps 132 coupling contact pads (not shown) on the underside of the die 102 to solder bump pads 134 on top layer of a backend of line (BEOL) that includes interconnection lines in layers and via holes 122 in a substrate 120 and an array of ball-grid array (BGA) pads 124 for connection to solder balls 126. The die 102 is held in place using underfill 136. Diagram 100C shows a number of example higher density integrated circuit (IC) packages, namely, embedded wafer level ball-grid array (eWLB) packages. The example IC packages include eWLB-PoP 142, 3D face-to-face package 144, eWLB with interposer 146, MEMS / Sensor eWLB 148, 3D eWLB SiP 150. Extended eWLB (2.5D) 152, multi-chip eWLB 154, eWLB SiP 156, single chip eWLB 158, flip chip eWLB 160, and eWLL 162.

The example IC configurations in diagrams 100B and 100C show attempts in technology to increase the number of interconnects by utilizing an underside of the IC package for connections as opposed to prior systems, where IC connections are made through pins on the side (s) of the package. While the use of ball-grid array (BGA) connections on a backend of line (BEOL) may increase the number of available connections, these configurations still carry the challenges discussed herein such as power consumption, heat generation, and signal delays, as well as limitations on a number of interconnections, size, and clock frequency capability.

The embedded wafer level ball-grid array (eWLB) packages shown in diagram 100D a packaging technology, where the package interconnects may be applied on an artificial wafer made of silicon chips and a casting compound. The embedded wafer level ball-grid array (eWLB) is a further development of the wafer-level ball-grid array (BGA) technology with the aim to allow a fan-out and more space for interconnect routing.

Some of the embedded wafer level ball-grid array (eWLB) configurations (as well as other systems) may use interposer layers. For example, C2 and C4 are commonly used interposer layers that connect a small die in a flip chip ball-grid array (FCBGA) using flip chip on one side and ball-grid array (BGA) on the other side. This connection technique therefore may reduce a board or substrate space by making the same number of connections in a smaller space. C2 and C4 are abbreviations for controlled collapse of chip connection. C2 includes pillars and may typically be used for finer pitch devices when the ball-grid array (BGA) pad has a pitch of 180 micrometers or less. In the C4 technique, solder bumps may be deposited on a die’s pads situated on the top side of a silicon wafer during the final wafer processing step. The die may then be mounted to external circuitry through a substrate, which may be another organic material circuit board.

A majority, if not all, of the illustrated example techniques include solder balls for connection. Thus, in most cases, at least two different conductive materials are used in the interconnection. Multiple materials may result in impedance mismatches and consequently in increased power consumption, heat generation, and signal delays, which may become worse at higher frequencies. Furthermore, multiple layers of the backend of line (BEOL) and/or interposers may also contribute to the power consumption and signal delays.

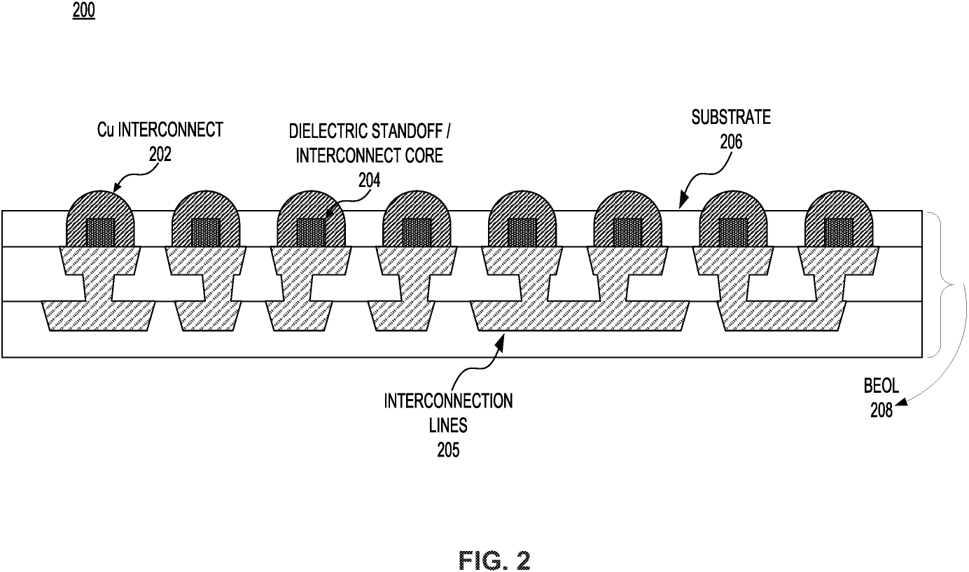

FIG. 2 illustrates a cross-sectional view of an IC interconnect system with small-size, high-density, copper interconnects, according to an example. Diagram 200 shows copper (Cu) interconnects 202 having dielectric or metallic interconnect core standoffs 204 and extruding from substrate 206 on a top layer of a backend of line (BEOL) 208 with interconnection lines 205 in at least one of the layers of backend of line (BEOL) 208.

While aluminum or tungsten have been traditionally used in integrated semiconductor devices, copper has a conductivity that is about twice that of aluminum and over three times that of tungsten. Thus, copper lines may carry larger currents and consume less power, or narrower lines may be designed reducing circuitry area. Copper is also mechanically superior to aluminum (less susceptible to degradation and breakage).

In some examples, a Damascene lithography process may be employed to fabricate an interconnect system with copper interconnects 202 allowing a size of the interconnects to be reduced to nanometer range, thereby increasing the density of the integrated circuit (IC) substantially, while also reducing power consumption and heat generation. The Damascene lithography process involves deposition of a diffusion barrier over a patterned substrate to prevent diffusion of copper atoms into the substrate and to provide improved adhesion for copper. A thin seed copper layer may be deposited over the diffusion barrier, followed by electroplating of a copper layer. It should be appreciated that the seed layer may be related to a nucleation process or the beginning of an induced preferential direction of growth . Subsequent electroplating layers may adhere to the seed copper layer and, thereby, to the underlying structure. Excess copper (and any other layer portions) may be removed by a chemical mechanical polishing process (CMP). Depending on the structure to be formed (e.g., interconnects), several stages of photoresist deposition, patterning, and etching, as well as multiple stages of copper electroplating may be applied. As solder bumps are not needed in an example interconnect system (or any other type of metal), impedance mismatch may be avoided, reducing signal delays and allowing higher clock frequencies to be implemented without performance degradation. The reduction of size, thereby a footprint of the interconnect array, may allow reduction of backend of line (BEOL) 208 layers because shorter interconnection lines may be sufficient to provide the couplings.

In some examples, higher standoff height (compared to wafer-to-wafer “W2W” and conventional bonding) of the interconnects 202 may allow for improved interconnect bonding. Furthermore, the example interconnect system may be compatible with advanced logic integrated circuits (ICs), even estimated future size ranges of 3 nanometers and below. Example interconnect systems may be used in memory and logic circuit applications.

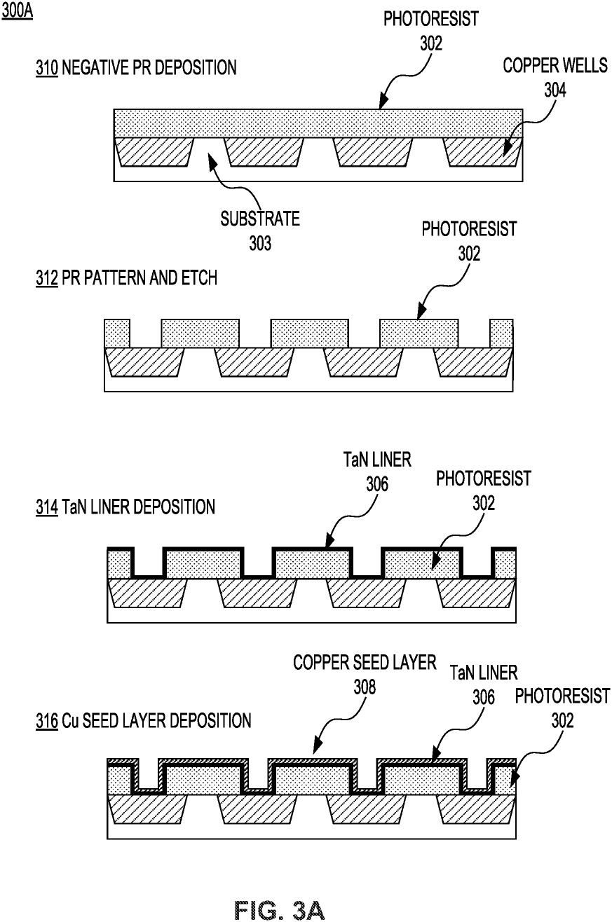

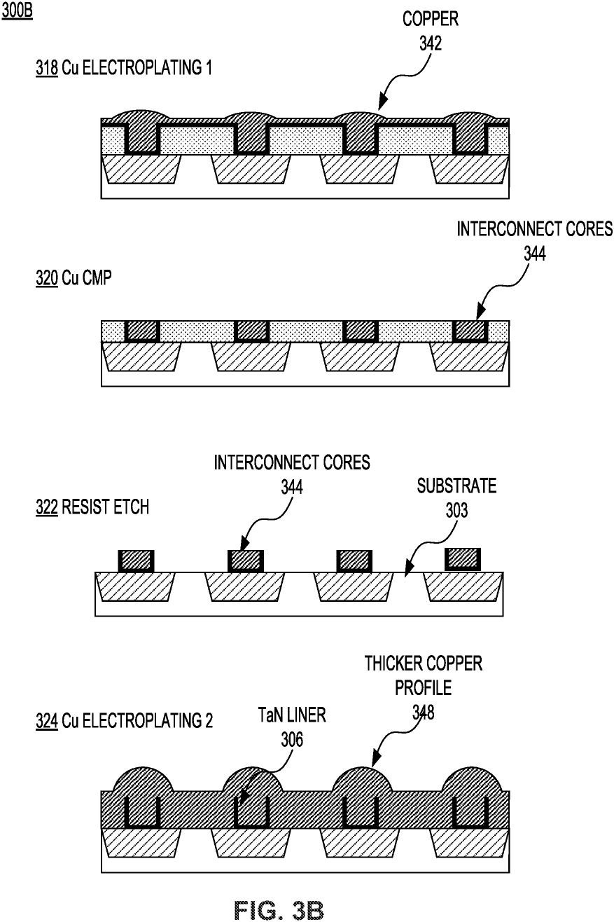

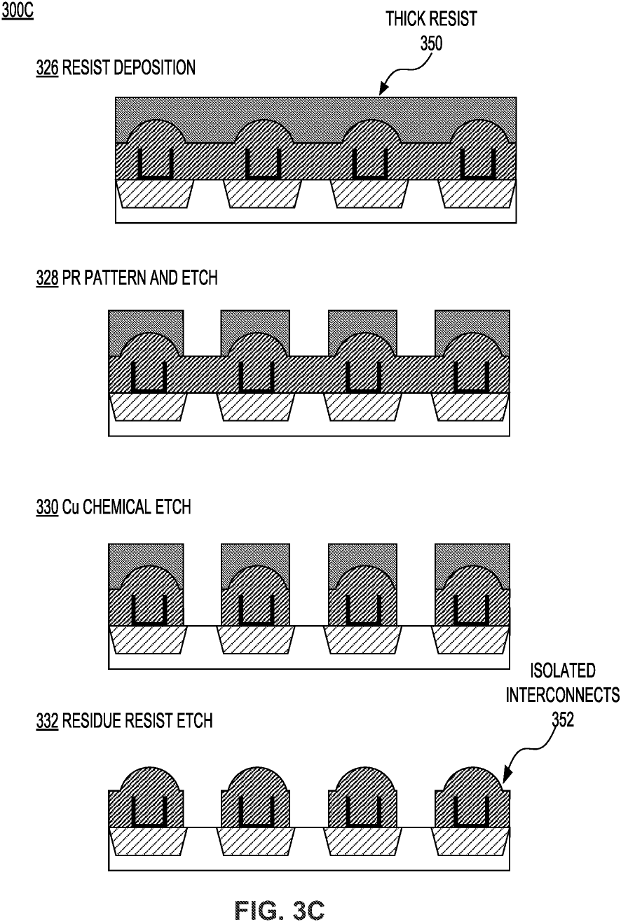

FIGS. 3A through 3C illustrate cross-sectional views of a small-size, high-density copper interconnect system in various stages of fabrication, according to an example. Diagrams 300A, 300B, and 300C in FIGS. 3A, 3B, and 3C show twelve consecutive example stages of the fabrication process.

In some examples, a substrate 303 implanted with copper wells 304 may be covered with a negative photoresist layer 302 through deposition at negative photoresist deposition stage 310. A negative photoresist is a light-sensitive organic material, which becomes insoluble to a photoresist developer when exposed to light (by becoming either polymerized or cross-linked). Examples of negative photoresist material may include, but are not limited to, epoxy-based polymer, off-stoichiometry thiol-enes (OSTE) polymer, and hydrogen silses quioxane (HSQ). The photoresist layer 302 may be applied to the substrate through spin-coating, plasma deposition, precision droplet-based spraying, etc. At the first photoresist pattern and etch module 404, a light-preventing patterned mask may be applied to the photoresist layer and exposed to light, for example, ultra-violet (UV) light.

In some examples, the photoresist layer 302 may be masked and selectively dissolved at photoresist pattern and etch stage 312. For selective dissolving, the mask may cover selected areas of the photoresist to be removed such that other areas become insoluble upon exposure to light (e.g., visible spectrum, UV light). The unexposed portions of the photoresist layer 302 over the copper wells 304 may be dissolved by a photoresist developer (e.g., dilute sodium or potassium carbonate-based solvents). In some examples, portions of the photoresist layer may be removed using other techniques such as laser evaporation, plasma etching, chemical etching, etc.

In some examples, a barrier metal film such as a Tantalum Nitride (TaN) liner 306 may be deposited over the remnants of the photoresist layer 302 and exposed surfaces of the copper wells 304 at TaN liner deposition stage 314. The TaN liner 306 may be deposited by sputtering, physical vapor deposition (PVD), chemical vapor deposition (CVD), atomic layer deposition (ALD), or similar processes in some example implementations. The TaN liner 306 may help prevent intermixing of materials above and below the barrier and stop copper diffusion. Other example barrier metal film materials may include, but are not limited to, Titanium Nitride (TiN).

In some examples, a seed copper layer 308 may be deposited over the TaN liner 306 (also covering remaining portions of the photoresist layer 302) at seed copper layer deposition stage 316. The seed copper layer 308 may also be deposited by sputtering, physical vapor deposition (PVD), chemical vapor deposition (CVD), atomic layer deposition (ALD), or similar processes and may be used to deposit (grow) copper plating at a subsequent stage.

In some examples, a copper layer 342 may be deposited over the seed copper layer 308 through electroplating at copper electroplating 1 stage 318. The electroplating of copper may fill the cavities formed by the patterns and etching and form slight bumps over the cavities compared to the higher, flat surfaces between the cavities. The electroplating may include, but is not limited to, immersion in an aqueous solution of cupric sulfate or similar.

In some examples, a surface portion including the top copper layer and the top TaN layers may be removed through chemical-mechanical polishing (CMP) at copper chemical-mechanical polishing (CMP) stage 320. The process may leave interconnect cores 344 exposed on the surface interspersed between photoresist layer 302 portions. The copper- filled and TaN lined cavities may form the interconnect cores 344. While the example configuration is shown with the cores being filled with copper, other metals or even dielectric material may also be used to fill the cores. Copper filing may simplify and speed the process. Yet, the cores help form and support a contour of the interconnects, and their fillers may not be relevant to the electrical characteristics of interconnects. Furthermore, the shape of the cores may also be any suitable shape and is not limited to the rectangular shape shown in the diagram. In some examples, grinding, electro-chemical mechanical planarization (ECMP), or similar removal techniques may be used instead of or in addition to chemical-mechanical polishing (CMP).

In some examples, remaining portions of the photoresist layer 302 may be removed at resist etch stage 322. As the remaining portions of the photoresist layer 302 are not masked and exposed to light at the photoresist pattern and etch stage 312, these portions may be insoluble. Thus, instead of a photoresist developer, an etchant may be used to remove the remaining portions of the photoresist layer 302.

In some examples, additional copper electroplating may be performed to generate a thicker copper profile 348 for the interconnection at copper electroplating 2 stage 324, for example, through immersion in an aqueous solution of cupric sulfate or similar. In some examples, a larger grain, thicker copper solution may be used for the second electroplating over the first electroplated copper layer. The second copper layer may fill the voids between the cores while forming bumps over the top areas of the cores.

In some examples, a thick resist 350 (photoresist layer) may be deposited through spin coating at resist deposition stage 326 to allow higher thicknesses in order to reduce a waviness created on the surface of the copper layer at the copper electroplating 2 stage 324. In some cases, a viscosity (thickness) of the photoresist used at the resist deposition stage 326 may be adjusted based on a particular height of the interconnects for a specific implementation.

In some examples, the thick resist layer 350 may be masked, exposed to light, and etched at photoresist pattern and etch stage 328 to expose the copper in between the interconnections. As in the photoresist pattern and etch stage 312, the mask may cover areas of the photoresist to be removed (areas between the interconnects) such that other areas become insoluble upon exposure to light (e.g., ultra-violet “UV” light). The unexposed portions of the thick resist layer 350 between the interconnects may be dissolved by a photoresist developer (e.g., dilute sodium or potassium carbonate based solvents).

In some examples, a chemical etching of the exposed copper may be performed at copper chemical etch stage 330 to isolate the interconnections from one another. Hydrochloric acid, ferric chloride solution, or comparable etchants may be used to etch the copper layer portions between the interconnections.

In some examples, remaining thick resist layer portions over the interconnects may be removed at residue resist etch stage 332 to expose isolated interconnects 352. As the remaining thick resist layer portions may be insoluble an etchant may be used to remove the remaining thick resist layer portions instead of a photoresist developer. A thickness of the copper, TaN, photoresist, and thick resist layers may be selected based at least in part on a pitch and/or final size (all three dimensions) of the interconnect system.

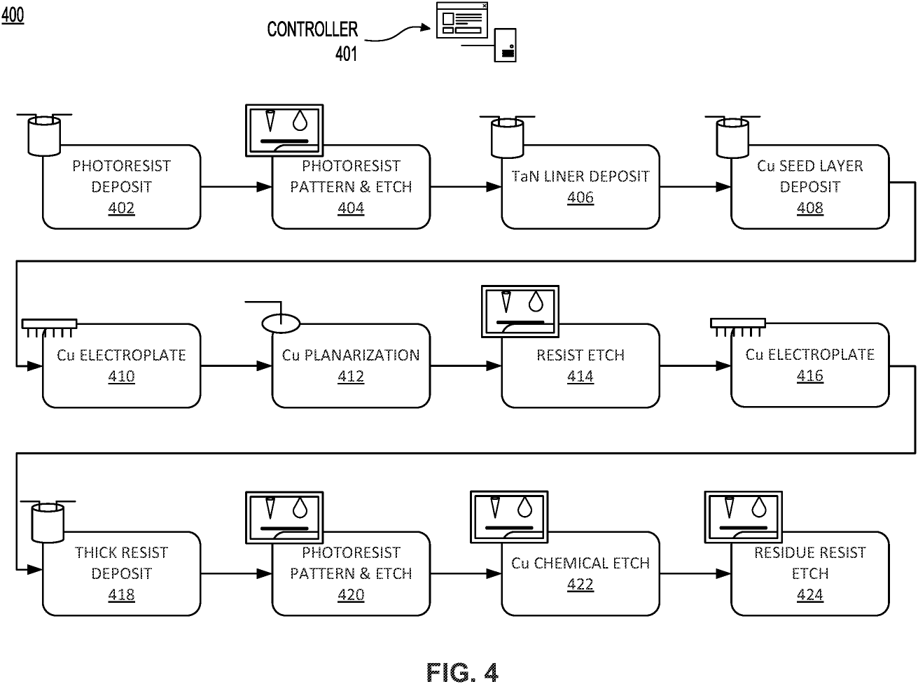

FIG. 4 illustrates a functional block diagram of a system to fabricate a small-size, high-density, copper interconnect system, according to an example. Functional block diagram 400 includes photoresist deposition module 402, first photoresist pattern and etch module 404, TaN liner deposition module 406, seed copper layer deposition module 408, first copper electroplating module 410, copper planarization module 412, resist etching module 414, second copper electroplating module 416, thick resist deposition module 418, second photoresist pattern and etch module 420, copper chemical etching module 422, residue resist etching module 424, and controller 401.

In some examples, a substrate implanted with copper wells may be covered with a photoresist layer at a deposition station (photoresist deposition module 402) through spin-coating, plasma deposition, precision droplet-based spraying, or comparable techniques. The photoresist layer may be patterned (covered by a mask), exposed to light (e.g., ultra-violet “UV” light), and unexposed portions of the photoresist layer over the copper wells may be removed at first photoresist pattern and etch module 404. The unexposed portions of the photoresist layer may be removed by dissolving using a photoresist developer (e.g., dilute sodium or potassium carbonate based solvents), for example, by dipping the substrate with the exposed photoresist layer in a solution tank.

In some examples, the substrate with partial photoresist layer may be deposited with a TaN liner at TaN liner deposition module 406 through sputtering, physical vapor deposition (PVD), chemical vapor deposition (CVD), atomic layer deposition (ALD), or similar processes. The TaN liner deposition module 406 may be a deposition chamber or similar. At the seed copper layer deposition module 408, a seed layer film of copper may be deposited over the TaN liner to help deposit the thicker copper layer deposited at the subsequent stage. The seed copper layer may also be deposited in a deposition chamber through sputtering, physical vapor deposition (PVD), chemical vapor deposition (CVD), atomic layer deposition (ALD), or similar processes.

In some examples, a copper layer may be deposited over the seed copper layer at the first copper electroplating module 410. The first copper electroplating module 410 may be an electroplate bath, where the wafer (substrate and deposited layers) to be plated is submerged into an electrolyte bath, a current applied, and copper layer formed on regions with the seed copper layer through migration of copper ions. At the copper planarization module 412, the top copper and TaN layers may be planarized. The copper planarization module 412 may include a rotating pad with liquid application, where an abrasive and corrosive chemical slurry may be applied to the wafer on a polishing pad. The pad and wafer may be pressed together by a dynamic polishing head and held in place by a retaining ring. The dynamic polishing head may be rotated with different axes of rotation removing material and evening out any irregular topography (planarization).

In some examples, the planarized wafer may then be subjected to chemical etching at the resist etch module 414 to remove remaining portions of the photoresist layer. A second copper electroplating may add a thicker layer of copper at the second copper electroplating module 416, which may be a separate electroplating station or the same station as the first copper electroplating module 410. A thick photoresist layer may be deposited through spin coating at thick resist deposition module 418 to allow higher thicknesses in order to reduce a waviness created on the surface of the copper layer at the second copper electroplating module 416.

In some examples, the thick photoresist layer deposited at the thick resist deposition module 418 may be masked, exposed to light, etched at photoresist pattern and etch module 420 to expose the copper in between the interconnections. The photoresist pattern and etch module 420 may be a separate station or the same station as the photoresist pattern and etch module 404 in the fabrication system. The exposed copper layer portions between the interconnects may be removed at the copper chemical etch module 422 through the application of an acid such as ferric chloride solution. The copper chemical etches module 422 may include one or more baths to apply etchant and another cleaning, polishing solutions to the wafer. In some examples, other removal methods (e.g., plasma etching) may also be used. At the residue resist etch module 424, the remaining portions of the thick resist on the interconnects may be removed. The residue resist etch module 424 may be the same station as the resist etch module 414 or a separate station in the fabrication system.

The modules (stations) of an example fabrication system to produce small-size, high-density, copper interconnects as described herein are for illustration purposes and do not imply limitations on the fabrication system. Some of the modules may be implemented as a single station performing any number of functions at different stages of fabrication. The fabrication system may also be implemented using fewer or additional modules using the principles described herein.

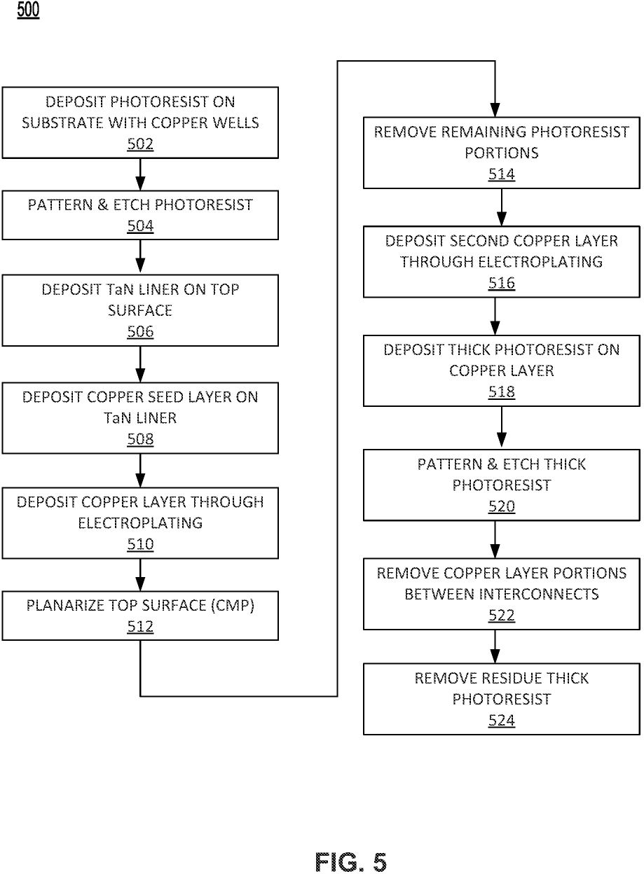

FIG. 5 illustrates a flowchart of a method to fabricate a small-size, high-density, copper interconnect system, according to an example. Each block shown in FIG. 5 may further represent one or more processes, methods, or subroutines, and one or more of the blocks may include machine-readable instructions stored on a non-transitory computer readable medium and executed by a processor or other type of processing circuit to perform one or more operations described herein.

At 502, a photoresist layer 302 may be deposited onto a substrate 303 implanted with copper wells through spin-coating, plasma deposition, precision droplet-based spraying, or comparable techniques at photoresist deposition module 402. At 504, the photoresist layer 302 may be patterned (covered by a mask), exposed to light (e.g., ultra-violet “UV” light), and unexposed portions of the photoresist layer over the copper wells may be removed at photoresist pattern and etch module 404. At 506, a TaN liner 306 may be deposited over the exposed portions of the copper wells and remaining portions of the photoresist layer 302 at TaN liner deposition module 406 through sputtering, physical vapor deposition (PVD), chemical vapor deposition (CVD), atomic layer deposition (ALD), or similar processes.

At 508, a seed copper layer 308 may be deposited over the TaN liner 306 at the TaN liner deposition module 406 to help deposit the thicker copper layer deposited at the subsequent stage. The seed copper layer 308 may also be deposited in a deposition chamber through sputtering, physical vapor deposition (PVD), chemical vapor deposition (CVD), atomic layer deposition (ALD), or similar processes. At 510, a copper layer 342 may be deposited over the seed copper layer 308 at the first copper electroplating module 410, which may be an electroplate bath.

At 512, the top copper and TaN layers (342, 306) may be planarized at the copper planarization module 412 through chemical-mechanical polishing (CMP). At 514, the planarized wafer may then be subjected to chemical etching at the resist etch module 414 to remove remaining portions of the photoresist layer and leaving exposed interconnect cores 344. At 516, a second copper electroplating may add a thicker copper profile 348 over exposed surface of the substrate 303, interconnect cores 344, and copper wells 304 at the second copper electroplating module 416.

At 518, a thick photoresist layer 350 may be deposited through spin coating over the thicker copper profile 348 at thick resist deposition module 418 to allow higher thicknesses in order to reduce a waviness created on the surface of the thicker copper profile 348. At 520, the thick photoresist layer 350 deposited at the thick resist deposition module 418 may be masked, exposed to light, and etched at photoresist pattern and etch module 420 to expose the copper in between the interconnections. At 522, the exposed copper layer portions between the interconnects 352 may be removed at the copper chemical etch module 422 through application of an acid such as ferric chloride solution. At 524, remaining portions of the thick photoresist layer 350 on the interconnects 352 may be removed at the residue resist etch module 424. Some of the modules of an example fabrication system may be the same station as other modules or separate stations in the fabrication system.

According to some examples, a method to fabricate an interconnect system for an integrated circuit (IC) is described. An example method may include processing a substrate implanted with copper wells with a first photoresist layer such that remaining portions of the first photoresist layer expose portions of the copper wells; depositing a barrier layer over the exposed portions of the copper wells and the remaining portions of the first photoresist layer; depositing a seed copper layer over the barrier layer; depositing a first copper layer over the seed copper layer; planarizing the first copper layer and portions of the barrier layer such that interconnect cores are exposed over the copper wells; depositing a second copper layer over exposed portions of the substrate, the copper wells, and the interconnect cores; removing portions of the second copper layer between interconnects by processing the second copper layer with a second photoresist layer; and removing remaining portions of the second photoresist layer on the interconnects.

According to some examples, processing the substrate with the first photoresist layer may include depositing the first photoresist layer on the substrate and the copper wells; masking the first photoresist layer with a patterned mask; exposing the masked first photoresist layer to ultra-violet (UV) light; and selectively dissolving unexposed portions of the first photoresist layer. Depositing the barrier layer may include depositing a Tantalum Nitride (TaN) liner by sputtering, physical vapor deposition (PVD), chemical vapor deposition (CVD), and/or atomic layer deposition (ALD), or other similar technique. Depositing the seed copper layer may include depositing the seed copper layer on the TaN liner by sputtering, physical vapor deposition (PVD), chemical vapor deposition (CVD), and/or atomic layer deposition (ALD), or other similar technique. A pattern of the TaN liner may form a boundary for the interconnect cores over the copper wells, and depositing the first copper layer over the seed copper layer may include filling the interconnect cores with copper.

According to some examples, planarizing the first copper layer and the portions of the barrier layer may include removing a top portion of the first copper layer and top portions of the barrier layer through chemical-mechanical polishing (CMP). Depositing a second copper layer over the exposed portions of the substrate, the copper wells, and the interconnect cores may include depositing a thick copper profile over the exposed portions of the substrate, the copper wells, and the interconnect cores. Removing the portions of the second copper layer between the interconnects may include depositing the second photoresist layer on the second copper layer; masking the second photoresist layer with a patterned mask; exposing the masked second photoresist layer to ultra-violet (UV) light; selectively dissolving unexposed portions of the second photoresist layer such that the portions of the second copper layer between the interconnects are exposed; and chemically etching the exposed portions of the second copper layer between the interconnects.

According to some examples, the method may further include selecting one or more of a type or a viscosity of the second photoresist layer based on a particular height of the interconnects. The method may also include depositing the first copper layer and the second copper layer by electroplating. The method may further include removing exposed portions of the first photoresist layer and the second photoresist layer through chemical etching.

According to some examples, a system to fabricate interconnects for an integrated circuit (IC) is described. An example system may include a first photoresist deposition module to cover a substrate implanted with copper wells with a first photoresist layer; a first photoresist pattern and etch module to selectively dissolve the first photoresist layer such that remaining portions of the first photoresist layer expose portions of the copper wells; a barrier layer deposition module to deposit a barrier layer over the exposed portions of the copper wells and the remaining portions of the first photoresist layer; a seed copper layer deposition module to deposit a seed copper layer over the barrier layer; a first copper electroplating module to deposit a first copper layer over the seed copper layer; a copper planarization module to planarize the first copper layer and portions of the barrier layer such that interconnect cores are exposed over the copper wells; a photoresist etch module to remove portions of the first photoresist layer between the interconnect cores; a second copper electroplating module to deposit a second copper layer over exposed portions of the substrate, the copper wells, and the interconnect cores; a second photoresist deposition module to cover second copper layer with a second photoresist layer; a second photoresist pattern and etch module to selectively dissolve portions of the second photoresist layer between the interconnects; a copper chemical etch module to remove portions of the second copper layer between the interconnects; and a residue resist etch module to remove remaining portions of the second photoresist layer on the interconnects.

According to some examples, the first photoresist deposition module and the second photoresist deposition module may be the same module; the first photoresist pattern and etch module and the second photoresist pattern and etch module may be the same module; or the first copper electroplating module and the second copper electroplating module may be the same module. The copper planarization module may planarize the first copper layer and the portions of the barrier layer through chemical-mechanical polishing (CMP). The second photoresist deposition module may select one or more of a type or a viscosity of the second photoresist layer based on a particular height of the interconnects. The barrier layer deposition module may deposit the barrier layer using Tantalum Nitride (TaN) by sputtering, physical vapor deposition (PVD), chemical vapor deposition (CVD), and/or atomic layer deposition (ALD), or other similar technique.

According to some examples, an interconnect apparatus for an integrated circuit (IC) may include a plurality of interconnects on a first layer of a backend of line (BEOL) wafer; a plurality of copper wells in a second layer of the BEOL; a plurality of copper vias in a third layer of the BEOL, the plurality of copper vias coupled to bottom surfaces of corresponding copper wells in the second layer; and a plurality of interconnection lines in one or more additional layers of the BEOL, the plurality of interconnection lines coupled to selected vias in the third layer, where a separation distance between the plurality of interconnects may be selected based at least in part on a size of the die, a pitch between the interconnects, and Damascene process settings. In some illustrative examples, not limiting implementations, the separation distance may be in a range of tens of nanometers, for example, from about200 nanometers to about 1000 nanometers, the plurality of interconnects may be supported by a plurality of interconnect cores, and each interconnect may be situated over and coupled to a corresponding copper well.

According to some examples, the plurality of interconnect cores may include Tantalum Nitride (TaN) liner walls and are filled with copper. The plurality of interconnects may be formed through at least two stages of copper electroplating over the plurality of interconnect cores. A shape of the plurality of interconnect cores may be selected based on a shape of the plurality of interconnects.

In the foregoing description, various inventive examples are described, including devices, systems, methods, and the like. For the purposes of explanation, specific details are set forth in order to provide a thorough understanding of examples of the disclosure. However, it will be apparent that various examples may be practiced without these specific details. For example, devices, systems, structures, assemblies, methods, and other components may be shown as components in block diagram form in order not to obscure the examples in unnecessary detail. In other instances, well-known devices, processes, systems, structures, and techniques may be shown without necessary detail in order to avoid obscuring the examples.

The figures and description are not intended to be restrictive. The terms and expressions that have been employed in this disclosure are used as terms of description and not of limitation, and there is no intention in the use of such terms and expressions of excluding any equivalents of the features shown and described or portions thereof. The word “example” is used herein to mean “serving as an example, instance, or illustration.” Any embodiment or design described herein as “example’ is not necessarily to be construed as preferred or advantageous over other embodiments or designs.

Although the methods and systems as described herein may be directed mainly to digital content, such as videos or interactive media, it should be appreciated that the methods and systems as described herein may be used for other types of content or scenarios as well. Other applications or uses of the methods and systems as described herein may also include social networking, marketing, content-based recommendation engines, and/or other types of knowledge or data-driven systems.

1. A method to fabricate an interconnect system for an integrated circuit (IC), the method comprising:
fabricating a substrate implanted with copper wells with a first photoresist layer such that remaining portions of the first photoresist layer expose portions of the copper wells;
depositing a barrier layer over the exposed portions of the copper wells and the remaining portions of the first photoresist layer;
depositing a seed copper layer over the barrier layer;
depositing a first copper layer over the seed copper layer;
planarizing the first copper layer and portions of the barrier layer such that interconnect cores are exposed over the copper wells;
depositing a second copper layer over exposed portions of the substrate, the copper wells, and the interconnect cores;
removing portions of the second copper layer between interconnects by processing the second copper layer with a second photoresist layer; and
removing remaining portions of the second photoresist layer on the interconnects.

2. The method of claim 1, wherein processing the substrate with the first photoresist layer comprises:
depositing the first photoresist layer on the substrate and the copper wells;
masking the first photoresist layer with a patterned mask;
exposing the masked first photoresist layer to ultra-violet (UV) light; and
selectively dissolving unexposed portions of the first photoresist layer.

3. The method of claim 1, wherein depositing the barrier layer comprises:
depositing a Tantalum Nitride (TaN) liner by at least one of sputtering, physical vapor deposition (PVD), chemical vapor deposition (CVD), or atomic layer deposition (ALD).

4. The method of claim 3, wherein depositing the seed copper layer comprises:
depositing the seed copper layer on the TaN liner by at least one of sputtering, physical vapor deposition (PVD), chemical vapor deposition (CVD), or atomic layer deposition (ALD).

5. The method of claim 4, wherein a pattern of the TaN liner forms a boundary for the interconnect cores over the copper wells, and depositing the first copper layer over the seed copper layer comprises:
filling the interconnect cores with copper.

6. The method of claim 1, wherein planarizing the first copper layer and the portions of the barrier layer comprises:
removing a top portion of the first copper layer and top portions of the barrier layer through chemical-mechanical polishing (CMP).

7. The method of claim 1, wherein depositing a second copper layer over the exposed portions of the substrate, the copper wells, and the interconnect cores comprises:
depositing a thick copper profile over the exposed portions of the substrate, the copper wells, and the interconnect cores.

8. The method of claim 1, wherein removing the portions of the second copper layer between the interconnects comprises:
depositing the second photoresist layer on the second copper layer;
masking the second photoresist layer with a patterned mask;
exposing the masked second photoresist layer to ultra-violet (UV) light;
selectively dissolving unexposed portions of the second photoresist layer such that the portions of the second copper layer between the interconnects are exposed; and
chemically etching the exposed portions of the second copper layer between the interconnects.

9. The method of claim 8, further comprising:
selecting one or more of a type or a viscosity of the second photoresist layer based on a particular height of the interconnects.

10. The method of claim 1, further comprising:
depositing the first copper layer and the second copper layer by electroplating.

11. The method of claim 1, further comprising:
removing exposed portions of the first photoresist layer and the second photoresist layer through chemical etching.

12. A system to fabricate interconnects for an integrated circuit (IC), the system comprising:
a first photoresist deposition module to cover a substrate implanted with copper wells with a first photoresist layer;
a first photoresist pattern and etch module to selectively dissolve the first photoresist layer such that remaining portions of the first photoresist layer expose portions of the copper wells;
a barrier layer deposition module to deposit a barrier layer over the exposed portions of the copper wells and the remaining portions of the first photoresist layer;
a seed copper layer deposition module to deposit a seed copper layer over the barrier layer;
a first copper electroplating module to deposit a first copper layer over the seed copper layer;
a copper planarization module to planarize the first copper layer and portions of the barrier layer such that interconnect cores are exposed over the copper wells;
a photoresist etch module to remove portions of the first photoresist layer between the interconnect cores;
a second copper electroplating module to deposit a second copper layer over exposed portions of the substrate, the copper wells, and the interconnect cores;
a second photoresist deposition module to cover second copper layer with a second photoresist layer;
a second photoresist pattern and etch module to selectively dissolve portions of the second photoresist layer between the interconnects;
a copper chemical etch module to remove portions of the second copper layer between the interconnects; and
a residue resist etch module to remove remaining portions of the second photoresist layer on the interconnects.

13. The system of claim 12, wherein
the first photoresist deposition module and the second photoresist deposition module are the same module;
the first photoresist pattern and etch module and the second photoresist pattern and etch module are the same module; or
the first copper electroplating module and the second copper electroplating module are the same module.

14. The system of claim 12, wherein the copper planarization module is to planarize the first copper layer and the portions of the barrier layer through chemical-mechanical polishing (CMP).

15. The system of claim 12, wherein the second photoresist deposition module is to select one or more of a type or a viscosity of the second photoresist layer based on a particular height of the interconnects.

16. The system of claim 12, wherein the barrier layer deposition module is to deposit the barrier layer using Tantalum Nitride (TaN) by at least one of sputtering, physical vapor deposition (PVD), chemical vapor deposition (CVD), or atomic layer deposition (ALD).

17. An interconnect apparatus for an integrated circuit (IC) comprising:
a plurality of interconnects on a first layer of a backend of line (BEOL) wafer;
a plurality of copper wells in a second layer of the BEOL;
a plurality of copper vias in a third layer of the BEOL, the plurality of copper vias coupled to bottom surfaces of corresponding copper wells in the second layer; and
a plurality of interconnection lines in one or more additional layers of the BEOL, the plurality of interconnection lines coupled to selected vias in the third layer, wherein:
the plurality of interconnects are supported by a plurality of interconnect cores, and
each interconnect is situated over and coupled to a corresponding copper well.

18. The interconnect system of claim 17, wherein the plurality of interconnect cores comprise Tantalum Nitride (TaN) liner walls and are filled with copper.

19. The interconnect system of claim 17, wherein the plurality of interconnects are formed through at least two stages of copper electroplating over the plurality of interconnect cores.

20. The interconnect system of claim 17, wherein a shape of the plurality of interconnect cores is selected based on a shape of the plurality of interconnects.
